(19) United States
(12) Patent Application Publication
(10) Pub. No.: US 2026/0360438 A1
(43) Pub. Date: Nov. 12, 2026

(54) Charge Trap Transistors

(71) Applicant: Cirrus Logic International Semiconductor Ltd., Edinburgh (GB)

(72) Inventors: John P. LESSO, Edinburgh (GB); Alexander BARR, Austin, TX (US)

(73) Assignee: Cirrus Logic International Semiconductor Ltd., Edinburgh (GB)

(21) Appl. No.: 19/355,321

(22) Filed: Oct. 10, 2025

Related U.S. Application Data
(60) Provisional application No. 63/802,960, filed on May 9, 2025.

(51) Int. Cl. G11C 16/14; G11C 16/04; G11C 16/10; G11C 16/26; G11C 16/34; H10B 43/30; H10D 8/00; H10D 30/69; H10D 64/66; H10D 64/68

(52) U.S. Cl. CPC G11C 16/14; G11C 16/0483; G11C 16/102; G11C 16/26; G11C 16/3445; G11C 16/3459; H10B 43/30; H10D 8/411; H10D 30/69; H10D 64/661; H10D 64/691

(57) ABSTRACT

Circuitry, comprising: a charge trap transistor (CTT) formed in a deep n-well; driver circuitry configured to locally heat the CTT by applying an n-well voltage to the deep n-well, the local heating increasing an emission rate of carriers from a charge trapping layer of the CTT.

### TECHNICAL FIELD

The present disclosure relates to charge trap transistors (CTTs) and circuitry comprising the same.

### BACKGROUND

In charge trap transistor (CTT) based non-volatile memories, conventional erasure techniques for de-trapping stored charge tend to suffer from power inefficiencies and incomplete charge removal. Bulk erase processes struggle to deliver sufficient localised heating while keeping power consumption low.

### SUMMARY

According to an aspect of the disclosure, there is provided circuitry, comprising: a charge trap transistor (CTT) formed in a deep well of a first conduction type; and driver circuitry configured to locally heat the CTT by applying a well voltage to the deep well, the local heating increasing an emission rate of carriers from a charge trapping layer of the CTT.

The first conduction type may be n-type or p-type. In the following summary clauses, the circuitry is described with the first conduction type being n-type, for example the CTT being an n-type device formed in a p-type substrate. Embodiments are not so limited. For example, in the below summary, reference to n-type may be substituted with p-type and reference to p-type substituted with n-type to describe a p-type CTT for example formed in an n-type substrate.

According to an aspect of the disclosure, there is provided circuitry, comprising: a charge trap transistor (CTT) formed in a deep n-well; and driver circuitry configured to locally heat the CTT by applying an n-well voltage to the deep n-well, the local heating increasing an emission rate of carriers from a charge trapping layer of the CTT.

The circuitry may comprise memory circuitry and the driver circuitry may be configured to locally heat the CTT as part of a memory erase operation.

The circuitry may comprise a p-type substrate, the deep n-well formed in the p-type substrate; and a p-well formed in the n-well, the CTT formed in the p-well.

The CTT may comprise: an n-type drain region formed in a surface of the p-well; a n-type source region formed in a surface of the p-well, the drain region laterally spaced-apart from the source region; a channel region extending laterally between the drain region and the source region; and a gate structure formed over the channel region.

The gate structure may comprise a silicon-oxide-nitride-oxide-silicon (SONOS) or metal-oxide-nitride-oxide-silicon (MONOS) stack, the stack comprising a tunnel oxide disposed over the channel region, a silicon nitride charge trapping layer disposed over the tunnel oxide, a blocking oxide disposed over the silicon nitride charge trapping layer, and a gate contact disposed over the blocking oxide. The gate contact may comprise polysilicon in the case of a SONOS device, or metal in the case of a MONOS device.

The gate structure may comprise a tunnel dielectric disposed over the channel region, the charge trapping layer disposed over the tunnel dielectric, a high-k blocking dielectric disposed over the charge trapping layer, and a gate contact disposed over the high-k blocking dielectric. The high-k blocking dielectric may comprise hafnium oxide, hafnium silicate, aluminum oxide, zirconium oxide, or a combination thereof.

The driver circuitry may be configured to locally heat the p-well of the CTT by applying the n-well voltage to the deep n-well to reverse bias a junction between the deep n-well and a p-well of the CTT into a conduction condition. The conduction condition may be a breakdown condition or an avalanche condition.

The circuitry may further comprise an n-well contact formed on a surface of the deep n-well, the driver circuitry configured to apply the n-well voltage using the n-well contact.

The n-well voltage may be time varying or pulsed. Alternatively, the n-well voltage may be a fixed or constant voltage.

The circuitry may further comprise control circuitry configured to adjust the n-well voltage to control a current flowing from the deep n-well to the CTT.

The control circuitry may be configured during a read operation to control the driver circuitry to: apply zero volts to a source of the CTT; apply a drain voltage to a drain of the CTT; and apply a read voltage at a gate of the CTT, the read voltage between an erased threshold voltage of the CTT in an erased state and a programmed threshold of the CTT in a programmed state. The control circuitry may be further configured to measure a current at the drain to determine a state of the CTT.

Subsequent to determining that the CTT is in a programmed state, the control circuitry may be further configured to adjust a magnitude of the n-well voltage applied to the deep n-well to erase the CTT. The magnitude of the n-well voltage may be adjusted based on the determined state of the CTT and one or more of a thermal model of the CTT and an electrical model of the CTT.

According to another aspect of the disclosure, there is provided a method of erasing or programming a charge trap transistor (CTT) formed in a deep n-well, the method comprising locally heating the CTT by applying an n-well voltage to the deep n-well, the local heating increasing an emission rate of carriers from a charge trapping layer of the CTT.

The CTT may be formed in a p-well formed in the deep n-well. The n-well voltage may be applied to the deep n-well to reverse bias a junction between the deep n-well and the p-well into a conduction condition. The conduction condition may comprise a breakdown condition or an avalanche condition.

The applied n-well voltage may be pulsed or time-varying.

The method may further comprise, after locally heating the CTT, performing a read operation to determine a state of the CTT, the state comprising a programmed state or an erased state; and adapting the n-well voltage based on the determined state of the CTT.

The method may further comprise repeating the step of locally heating the CTT by applying the n-well voltage to the deep n-well, a magnitude of the n-well voltage being greater than a previous local heating of the CTT.

The CTT may comprise: the p-well formed in the deep n-well; an n-type drain region formed in a surface of the p-well; a n-type source region formed in a surface of the p-well, the drain region laterally spaced-apart from the source region; a channel region extending laterally between the drain region and the source region; and a gate structure formed over the channel region.

According to another aspect of the disclosure, there is provided a method of erasing or programming a charge trap transistor (CTT) formed in a deep n-well, the method comprising: locally heating the CTT by applying a n-well voltage to the deep n-well to reverse bias a junction between the deep n-well and a p-well of the CTT into an avalanche condition.

According to another aspect of the disclosure, there is provided a non-volatile memory comprising the circuitry described above.

The memory may comprise NOR flash, NAND flash, embedded flash, or electrically erasable programmable read-only memory (EEPROM).

According to another aspect of the disclosure, there is provided an electronic device comprising the circuitry or the non-volatile memory described above.

The electronic device may comprise one of a mobile computing device, a laptop computer, a tablet computer, a games console, a remote-control device, a home automation controller or a domestic appliance, a toy, a robot, an audio player, a video player, or a mobile telephone, and a smartphone

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of a conventional charge trap transistor (CTT);

FIG. 2 is a schematic diagram of an example gate structure of the CTT of FIG. 1;

FIG. 3 is a graphical illustration of a programming operation performed on the CTT of FIG. 1;

FIG. 4 is a graphical illustration of an erase operation performed on the CTT of FIG. 1;

FIG. 5 is a schematic diagram of a CTT;

FIG. 6 is a graph illustrating the relationship between temperature and erase time for the CTT of FIG. 5; and

FIG. 7 is a flow chart illustrating a process for characterising parameters for erasure of the CTT of FIG. 5.

### DESCRIPTION OF EMBODIMENTS

Embodiments of the present disclosure aim to address or at least ameliorate one or more of the challenges associated with conventional charge trap transistors.

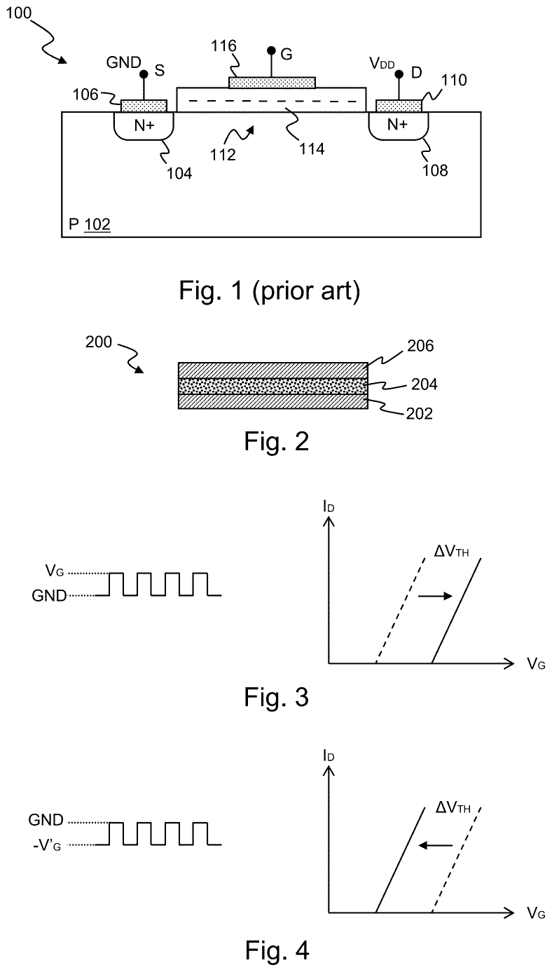

FIG. 1 is a schematic diagram of a known charge trap transistor (CTT) 100 formed in a p-type semiconductor substrate 102. The CTT comprises a gate G, source S, and drain D. The source S comprises a first n+ doped region 104 formed in an upper surface of the substrate 102 and a source contact 106 formed on the first n+ doped region 104. The drain D similarly comprises a second n+ doped region 108 formed in an upper surface of the substrate 102 and a drain contact 110 formed on the n+ doped region 108. The source and drain contact 105, 110 may be formed of a metal.

The first and second n+ doped regions 104, 108 are spaced apart by a channel region 112. For the gate G of the CTT 100, a gate structure is formed over the channel region 112 comprising a charge trapping layer 114 and a gate contact 116.

The charge trapping layer 114 may comprise multiple sub-layers engineered for the trapping of charge through direct tunnelling of carriers from the channel region 112 into the charge trapping layer 114.

For example, the CTT 100 may be a SONOS (silicon-oxide-nitride-oxide-silicon) device. In which case, the charge trapping layer 114 may comprise a stack 200 as shown in FIG. 2, the stack 200 comprising a tunnel oxide layer 202 disposed on the substrate 102, a silicon nitride layer 204 formed over the tunnel oxide layer 202, and a blocking dielectric layer 206 formed over the silicon nitride film 204. The silicon nitride film 204 provides localized trapping sites distributed throughout the bulk of the layer. The tunnel oxide layer 206 may be formed of silicon dioxide of a thickness ranging from about 2 nm to 6 nm to permit carrier tunneling from the channel region 112 into the silicon nitride film 204. The blocking dielectric layer 206 may comprise silicon dioxide or another oxide. The blocking dielectric layer 206 may inhibit charge leakage from the silicon nitride layer 204 to the gate contact 116. The gate contact may comprise polysilicon as is the case in SONOS devices, or alternatively may comprise a metal. In which case, the CTT 100 is a MONOS device.

It will be appreciated that the charge trapping layer 114 may be implemented using any other known charge trapping technology. For example, the charge trapping layer 114 may comprise a high-k metal oxide such as hafnium oxide (HfO₂), hafnium silicate (HfSiOₓ), aluminum oxide (Al₂O₃), or zirconium oxide (ZrO₂). Such high-k dielectrics provide oxygen vacancy defect states that act as charge trapping sites. In another example, the silicon nitride layer 204 of the stack 200 of FIG. 2 may be replaced by a plurality of discrete nanocrystals or nanoparticles (e.g. silicon, germanium, or metallic) embedded within a dielectric host material (e.g. silicon dioxide, silicon nitride, or a high-k dielectric). Each nanocrystal or nanoparticle may operate as an isolated charge storage node. In another example, the charge trapping layer 114 may be implemented as a TANOS (titanium-alumina-nitride-oxide-silicon) stack.

As illustrated in FIG. 3, the charge trapping layer 114 may be programmed by applying several positive voltage pulses at the gate G of the CTT 100 with the source S coupled to a reference voltage lower than the voltage at the drain D, such as ground GND. This leads to tunneling or hot carrier injection of carriers (e.g. electrons) into the charge trapping layer 114. This increase in charge in the charge trapping layer 114 leads to an increase in the threshold voltage VT of the CTT 100. Programming may alternatively be implemented by applying a constant positive voltage at the gate G.

As illustrated in FIG. 4, the charge trapping layer 114 may be erased or deprogrammed by applying several negative voltage pulse at the gate G of the CTT 100 with the source S coupled to ground GND, leading to reverse tunneling or hot-hole injection into the charge trapping layer 114. This decrease in charge in the charge trapping layer 114 leads to a decrease in the threshold voltage VT of the CTT 100. Erasing may alternatively be implemented by applying a constant negative voltage at the gate G.

The above-described conventional technique for erasing or deprogramming the CTT 100 often suffers from power inefficiency due to voltage required to deprogram being relatively high when compared to read operations. Erasure using lower gate voltages can lead to incomplete charge removal which can have knock on effects for subsequent programming accuracy. Moreover, bulk erase processes for multiple CTT devices often struggle to deliver sufficient localized heating while keeping power consumption down.

Embodiments of the present disclosure aim to address or at least ameliorate one or more of the above issues by an improved architecture and mechanism for erasing CTTs with increased energy efficiency and reliability.

It will be appreciated that programming and erasing of CTTs is affected by temperature. As temperature increases, the tunnelling probability increases due to carriers having higher thermal energy. During erasure of the CTT 100, carriers are emitted or detrapped from the charge trapping layer 114. The emission (or detrapping) rate e(T) of a trapped electron is governed by the Arrhenius equation and can therefore be described as follows:

$$e ( T ) = υ {e}^{( - \frac{{E}_{a}}{kT} )}$$

Where Eₐ is the activation energy, k is Boltzmann's constant, T is temperature, and v is the attempt-to-escape frequency. Thus, at higher temperatures, trapped charge escapes faster. Under this assumption, at room temperature de-trapping or erase of the CTT 100 may take years. However, if the temperature of the CTT 100 is increased to, say, 200 °C, the time taken for de-trapping or erase of the CTT 100 to take place may be reduced to tens of microseconds. Thus, it is desirable to increase the temperature of the charge trapping layer 114 during an erase process to improve overall time and energy efficiency.

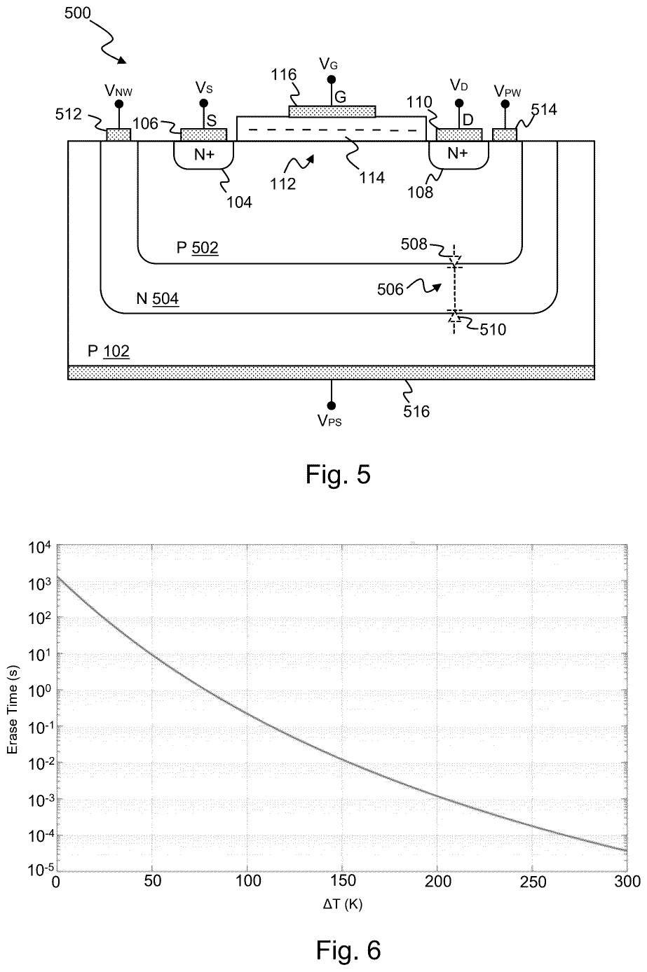

FIG. 5 is a schematic diagram of a known charge trap transistor (CTT) 500 according to embodiments of the present disclosure. Like parts of the CTT 500 been denoted with like reference numerals to the CTT 100 of FIG. 1. The CTT 500 differs from the CTT 100 of FIG. 1 in that instead of being formed directly in or on the semiconductor substrate 102, the source S, drain D, and gate G of the CTT 500 are formed in or on a p-well 502. The p-well 502 is formed wholly within an n-well 504. The n-well 504 is formed in the substrate 102.

Thus, the p-well 502, n-well 504 and p-type substrate 102 form a P-N-P structure 506 consisting of a first diode 508 between the p-well 502 and the n-well 504, and a second diode 510 between the p-type substrate 102 and n-well 504.

The n-well 504 may be a deep n-well formed by high-energy implantation of diffusion as is known in the art. The n-well 504 may extend several microns deeper into the substrate 102 than a standard n-well 504. For example, the n-well 504 may extend several microns (e.g. >3 microns) from the substrate 102 surface. Providing the n-well 504 as deep n-well enables the n-well to be biased independently of the global structure (e.g. the substrate 102).

Thus, by providing the CTT 500 in the deep n-well 504 the CTT 500 can be erased by applying a voltage between the n-well 504 and the p-well 502 to reverse bias the first diode 508 causing an avalanche condition in the first diode 508 formed at the junction between the n-well 504 and the p-well 502. The resultant rapid growth in current across the junction from the n-well 504 to the p-well 502 leads to localised joule heating in the p-well 504 which, in turn, increases the emission rate of carriers from the charge trapping layer 114.

Whilst in the embodiment show in FIG. 5 the CTT 500 is an n-type device formed in the p-well 502, embodiments are not so limited. In other embodiments, the CTT 500 may be a p-type device formed in an n-well. For example, instead of the p-type substrate 102, an n-type substrate may be provided, a deep p-well being formed in the p-type substrate, an n-well formed in the deep p-well, and a p-type CTT 500 formed in the n-well (e.g. with p-type source and drain regions).

By controlling the voltage applied across the junction between the n-well 504 and the p-well 502, localised heating can be controlled. Such control may be adaptive. Erasure of the CTT 500 can then be optimized to improve erase efficiency by determining the current required to obtain a required temperature in the p-well 502 necessary for erasure in a set time period. In doing so, heating above such temperature can be avoided and overcurrent can be reduced, thereby reducing power consumption associated with erase operations.

To enable the deep n-well 504 to be biased to a known voltage, an n-well contact 512 may be provided to contact the n-well 504. An n-well voltage VNW may then be applied to the n-well 504 via the n-well contact 512. Optionally, to enable the p-well 502 to be biased to a known voltage, a p-well contact 514 may be provided on the p-well 502. The p-well contact 514 may enable a p-well voltage VPW to be applied to the p-well 502. Optionally, a substrate contact 516 may be provided on the substrate 102 to enable a substrate voltage VPS. The substrate contact 516 may be provided as a back contact as shown in FIG. 5 or alternatively may be provided as a top contact.

There are various ways in which the CTT 500 may be erased. Several non-limiting examples will now be described.

In one possible scenario, the first diode 508 may avalanche before the second diode 510.

To erase the CTT 500, the substrate voltage VPS, a source voltage VS applied at the source S, and a drain voltage VD may be held at zero volts or ground. The n-well voltage VNW applied at the n-well contact 512 may then be raised high enough to cause avalanche breakdown at the first diode 508. The resultant current flowing into the p-well leads to localised heating which causes detrapping of charge in the charge trapping layer such that the CTT 500 is erased.

In another possible scenario, the second diode 510 may avalanche before the first diode 510. To avoid this scenario, the substrate voltage VPS may be raised so as to reduce the level of reverse bias applied to the second diode 510, thereby preventing avalanche breakdown of the second diode 510.

Thus, during an erase operation, the CTT 500 may be controlled not only by adjusting the n-well voltage VNW applied to the n-well 504, but also by controlling the voltage VPS applied to the substrate 102 to ensure the second diode 510 is not reverse-conducting during the erase operation. In doing so, current flowing into the substrate 102 from the n-well, which would otherwise lead to power loss and reduction in efficiency of heating of the p-well 502, may be eliminated or at least substantially reduced.

As noted above, by controlling the n-well voltage VNW, the p-well voltage VPW, and the substrate voltage VPS, the p-well 502 can be heated to improve the efficiency of erasure of the CTT 500. The n-well voltage VNW and/or the substrate voltage VPS may be adjusted (e.g. dynamically) to determine an optimal thermal condition for erasure.

To determine a current/required to obtain a necessary change in temperature required for an erase operation, an erase characterisation operation may be performed on the CTT 500. Such a process may consider one or more of thermal resistance, thermal capacitance, and activation energy models associated with the charge trapping layer 114. Such considerations will now be described.

Joule heating in the p-well 502 may be defined by the following equation:

P=I²R

where P is power I is current, and R is resistance.

The change in temperature ΔT of the p-well 502 from an ambient temperature TA before heating to a target temperature TT may be given by the following equation:

ΔT=T_{T}−T_{A}

However, the exact target temperature TT may be unknown. Accordingly, the temperature change ΔT can also be defined in terms of thermal resistance θ (degree/Watt) as shown below:

ΔT=Pθ

Thus, the current/needed to be supplied for a given temperature change ΔT can be defined as follows:

$$I = \sqrt{\frac{Δ T}{R θ}}$$

An estimate of the resistance R of the p-well 502 is given by the following equation:

$$R = \frac{L}{σ A} = \frac{L}{q {μ}_{P} {N}_{A} A}$$

where L is the depth of the p-well 502, A is the device area (width×length of p-well contact), and σ is the conductivity of the p-well 502. The conductivity σ is dependent on doping concentration and can be defined by the product of electron charge q mobility μₚ of majority carriers in the substrate 102, and doping concentration of acceptors N_{A} (in p-type material).

For an approximate resistance R of the p-well of 100Ω, a thermal resistance θ of 2000 k/W, and a target temperature change of 200 °C, the current/needed to be supplied is approximately 31 mA. For a target temperature change of 100 °C, a current needed to be supplied reduces to approximately 20 mA. It can be thus seen that a significant power saving can be realised by only heating the p-well 502 to a temperature required for erasure.

In some implementations, it may be preferable to apply a pulsed voltage to the n-well 504. In this case, thermal capacitance CTH is used rather than thermal resistance θ. A heat energy Q in joules may be defined as follows:

Q=C_{TH}·ΔT

Thermal capacitance CTH is given by the following equation:

C_{TH}=ρVc

where c is the specific heat capacity of the p-well 502, V is the volume of the p-well 502, and ρ is the material density of the p-well 502.

For bulk silicon, c=700 J/kg·K, ρ=2300 kg/m³, V=1 μm³. As such, the thermal capacitance CTH can be estimated at 1.6 ρJ/K.

It can then be shown that for a pulse of time tp, the current I needed for a temperature change ΔT is given by:

$$I = \sqrt{\frac{ρ Vc Δ T}{{Rt}_{P}}}$$

For a 1 microsecond pulse to achieve a temperature change ΔT of 200 °C, a current I of 56 mA is needed.

To determine whether a temperature change ΔT of 200 °C would reduce an average time for emission or detrapping from a charge trap, the above equation for emission rate e(T) can be reformulated to define an emission time constant T (the average time a carrier stays in a trap before escaping). The reformulated equation is as follows:

$${τ = τ}_{0} {e}^{( \frac{{E}_{A}}{kT} )}$$

where τ₀ is the attempt-to-escape time (characteristic time a trapper carrier would stay in a trap if there were no activation barrier). If the charge trapping layer 114 of the CTT 500 is implemented with a high-k dielectric such as hafnium oxide, the activation energy E_{A} is 0.9 V. At a temperature T of 300K (room temperature), the emission time constant is approximately 17 days. If the temperature is increase by 200 degrees to 500K, the emission time constant reduces to approximately 1.2 seconds.

The relationship between the emission time constant (erase time) t and temperature change ΔT is graphically illustrated in FIG. 6. It can be seen that as temperature increases, the emission time constant (erase time) of the CTT 500 decreases.

Having regard for the above, a characterisation process may be undertaken to determine a minimum temperature change ΔT required for complete detrapping or erasing of the CTT 500.

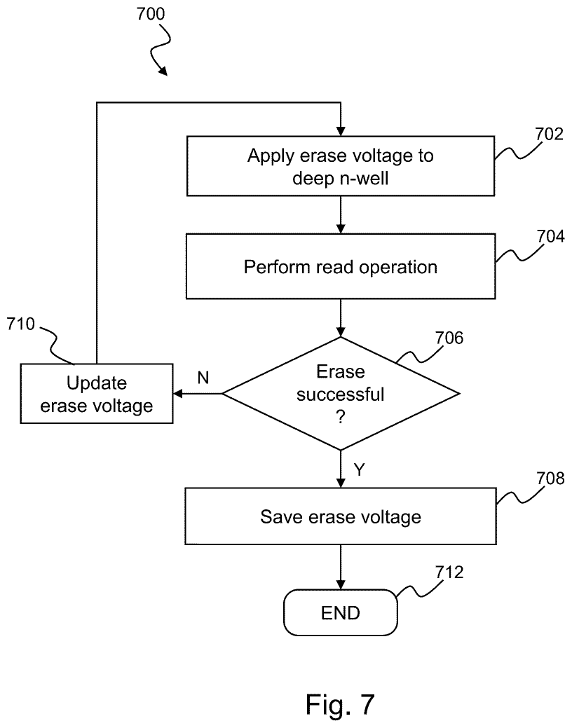

FIG. 7 is a flowchart showing an example process 700 for characterising erase parameters of the CTT 500.

At step 702, in an erase operation, the n-well voltage VWN of the CTT 500 is set to an erase voltage, placing the first diode (junction) 508 in a reverse bias. The erase voltage may be a constant voltage. Alternatively, the erase voltage may be a time-varying voltage, for example in the form of a plurality of pulses. The pulses may be in the form of a square wave, a sine wave or the like. Below a threshold reverse bias, the first diode 504 will be substantially non-conducting. Above the threshold reverse bias, the first diode 504 will avalanche, causing current to flow into the p-well 502 and associated joule heating of the p-well 502. As the erase voltage increases above the threshold reverse bias, the current flowing into the p-well 502 will increase, leading to an increase in temperature of the p-well. The high the temperature, the more likely that detrapping of charge from the charge trapping layer 114 will occur. After the erase operation is completed, the n-well voltage VNW may return to a baseline voltage, e.g. zero volts or ground.

At step 604, in a read operation, the gate voltage VG may be set to a fixed read voltage VREAD. The read voltage VREAD is chosen to be between the threshold voltage VTH of the cell 500 in an erased condition and the threshold voltage VTH of a cell 500 in a programmed condition. The source voltage VS (and preferably the substrate voltage VPS) are set to zero volts (or ground). A small positive bias is applied to the drain D via the drain voltage VD to draw current through the channel region 112. A current ID at the drain is then measured. If the cell is successfully erased at step 702, the read voltage VREAD is greater than the threshold voltage VTH of the cell 500. In which case, an inversion channel forms in the channel region 112, leading to current flowing from drain D to source S of the CTT 500. If the cell remains in a programmed state despite the erase operation at step 702, the read voltage VREAD applied at the gate G will be less than the threshold voltage VTH of the cell 500. In which case, no inversion channel will form in the channel region 112 and negligible current will flow between the drain D and source S of the CTT 500.

Thus, at step 706 a determination is made based on the read operation as to whether the erase operation at step 702 was successful. Such a determination may be made by comparing the measured drain current ID to a threshold. If the drain current ID is above a threshold, a determination may be made that the CTT 500 has been successfully erased. If not, then a determination may be made that the CTT 500 has not been erased by the erase operation.

If it is determined that the erase operation was successful, then at step 708 the erase voltage used in the erase operation at step 702 is saved for future erase operations.

If it is determined that the erase operation was unsuccessful, then the process proceeds to step 710 where the erase voltage value is updated. A failed erase operation may signify that the erase voltage was not high enough to cause sufficient heating of the p-well 502. Thus, the update may comprise increasing the erase voltage for use in subsequent erase operations. Where the erase voltage is time-varying, the update may comprise increasing a peak value of the erase voltage, or increasing the time at which the erase voltage is at the peak value. The update may be based solely on the measured state of the CTT 500 at step 706. Alternatively, the update may be based on one or both of a thermal model of the CTT 500 and an electrical model of the CTT 500. Such models may be based on the analysis provided above.

After the update, the process 700 returns back to step 702 where the n-well voltage VNW is set to the updated erase voltage.

Steps 704, 706, and 710 are repeated until it is determined at step 706 that the erase was successful, at which point the erase voltage used in the most recent erase operation at step 702 is saved at step 708 and the process ends at step 712.

The process 700 described above may be performed to characterise the cell so as determine an optimum n-well voltage VNW to apply to erase the CTT 500. The optimum n-well voltage VNW may be a minimum voltage required to erase the CTT 500. Whilst in the above process 700 voltage is discussed, it will be appreciated that such techniques are effective in determining an optimum current to be applied also.

CTTs disclosed herein may be implemented in a wide variety of semiconductor memory architectures and integrated circuit applications. For example, disclosed CTTs may be employed as a memory element in non-volatile memory arrays including, but not limited to, NOR flash, NAND flash, embedded flash, electrically erasable programmable read-only memory (EEPROM), and SONOS- or TANOS-type memories. Such devices may further be integrated into logic-compatible platforms, such as embedded non-volatile memory within standard CMOS logic processes, system-on-chip (SoC) devices, and microcontrollers. Practical applications include data storage, firmware retention, program code storage, configuration memory, and secure key storage in consumer, industrial, and automotive electronics. In addition, the disclosed CTTs may be utilized in advanced computing and neuromorphic architectures, where charge trapping characteristics enable multi-level storage or analog weight programming.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog TM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry, comprising:
a charge trap transistor (CTT) formed in a deep n-well; and
driver circuitry configured to locally heat the CTT by applying an n-well voltage to the deep n-well, the local heating increasing an emission rate of carriers from a charge trapping layer of the CTT.

2. The circuitry of claim 1, wherein the circuitry comprises memory circuitry, the driver circuitry configured to locally heat the CTT as part of a memory erase operation.

3. The c of claim 1, comprising:
a p-type substrate, the deep n-well formed in the p-type substrate; and
a p-well formed in the n-well, the CTT formed in the p-well.

4. The circuitry of claim 3, wherein the CTT comprises:
an n-type drain region formed in a surface of the p-well;
a n-type source region formed in a surface of the p-well, the drain region laterally spaced-apart from the source region;
a channel region extending laterally between the drain region and the source region; and
a gate structure formed over the channel region.

5. The circuitry of claim 4, wherein the gate structure comprises:
a silicon-oxide-nitride-oxide-silicon (SONOS) or metal-oxide-nitride-oxide-silicon (MONOS) stack, the stack comprising a tunnel oxide disposed over the channel region, a silicon nitride charge trapping layer disposed over the tunnel oxide, a blocking oxide disposed over the silicon nitride charge trapping layer, and a gate contact disposed over the blocking oxide.

6. The circuitry of claim 5, wherein the gate contact comprises polysilicon or metal.

7. The circuitry of claim 4, wherein the gate structure comprises a tunnel dielectric disposed over the channel region, the charge trapping layer disposed over the tunnel dielectric, a high-k blocking dielectric disposed over the charge trapping layer, and a gate contact disposed over the high-k blocking dielectric.

8. The semiconductor device of claim 7, wherein the high-k blocking dielectric comprises hafnium oxide, hafnium silicate, aluminum oxide, zirconium oxide, or a combination thereof.

9. The circuitry of claim 3, wherein the driver circuitry is configured to locally heat the p-well of the CTT by applying the n-well voltage to the deep n-well to reverse bias a junction between the deep n-well and a p-well of the CTT into a conduction condition.

10. The circuitry of claim 9, wherein the conduction condition is an avalanche condition.

11. The circuitry of claim 1, further comprising:
an n-well contact formed on a surface of the deep n-well, the driver circuitry configured to apply the n-well voltage using the n-well contact.

12. The circuitry of claim 1, wherein the n-well voltage is time varying.

13. The circuitry of claim 12, wherein the n-well voltage is pulsed.

14. The circuitry of claim 1, further comprising:
control circuitry configured to adjust the n-well voltage to control a current flowing from the deep n-well to the CTT.

15. The circuitry of claim 14, wherein the control circuitry is configured during a read operation to:
control the driver circuitry to:
apply zero volts to a source of the CTT;
apply a drain voltage to a drain of the CTT; and
apply a read voltage at a gate of the CTT, the read voltage between an erased threshold voltage of the CTT in an erased state and a programmed threshold of the CTT in a programmed state; and
measure a current at the drain to determine a state of the CTT.

16. The circuitry of claim 15, wherein subsequent to determining that the CTT is in a programmed state, the control circuitry may be further configured to adjust a magnitude of the n-well voltage applied to the deep n-well to erase the CTT.

17. The circuitry of claim 16, wherein the magnitude of the n-well voltage is adjusted based on the determined state of the CTT and one or more of a thermal model of the CTT and an electrical model of the CTT.

18. A method of erasing or programming a charge trap transistor (CTT) formed in a deep n-well, the method comprising:
locally heating the CTT by applying an n-well voltage to the deep n-well, the local heating increasing an emission rate of carriers from a charge trapping layer of the CTT.

19. The method of claim 18, wherein the CTT is formed in a p-well formed in the deep n-well, and wherein the n-well voltage is applied to the deep n-well to reverse bias a junction between the deep n-well and the p-well into a conduction condition.

20. The method of claim 19, wherein the conduction condition comprises an avalanche condition.

21. The method of claim 19, wherein the applied n-well voltage is pulsed or time-varying.

22. The method of claim 18, further comprising:
after locally heating the CTT, performing a read operation to determine a state of the CTT, the state comprising a programmed state or an erased state; and
adapting the n-well voltage based on the determined state of the CTT.

23. The method of claim 22, further comprising:
repeating the step of locally heating the CTT by applying the n-well voltage to the deep n-well, a magnitude of the n-well voltage being greater than a previous local heating of the CTT.

24. The method of claim 19, wherein the CTT comprises:
the p-well formed in the deep n-well;
an n-type drain region formed in a surface of the p-well;
a n-type source region formed in a surface of the p-well, the drain region laterally spaced-apart from the source region;
a channel region extending laterally between the drain region and the source region; and
a gate structure formed over the channel region.

25. A method of erasing or programming a charge trap transistor (CTT) formed in a deep n-well, the method comprising:
locally heating the CTT by applying a n-well voltage to the deep n-well to reverse bias a junction between the deep n-well and a p-well of the CTT into an avalanche condition.

26.-28. (canceled)

29. An electronic device comprising the circuitry of claim 1, wherein the device comprises a non-volatile memory, one of a mobile computing device, a laptop computer, a tablet computer, a games console, a remote-control device, a home automation controller or a domestic appliance, a toy, a robot, an audio player, a video player, or a mobile telephone, and a smartphone.
